(19) United States
(12) Patent Application Publication
(10) Pub. No.: US 2007/0144767 A1
(43) Pub. Date: Jun. 28, 2007

(54) LAYOUT STRUCTURE OF A CONDUCTION REGION OF A CPU SOCKET

(75) Inventor: Sheng-Yun Shu, Shenzhen (CN)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI PRECISION INDUSTRY CO., LTD., Tu-Cheng (TW)

(21) Appl. No.: 11/309,548

(22) Filed: Aug. 18, 2006

(30) Foreign Application Priority Data
Dec. 27, 2005 (CN) 200510121383.9

(51) Int. Cl. H05K 1/03

(52) U.S. Cl. 174/255; 174/262

(57) ABSTRACT

A layout structure of a conduction region of a CPU socket includes a power plane, and a plurality of pad pairs and grounding vias arrayed on the power plane. Each of the pad pairs having a grounding pad and a power supply pad for connecting an electronic component. Each grounding pad is coupled to at least a grounding via. The grounding pad and the power supply pad are arranged in rows and columns in an alternating pattern.

### 1. FIELD OF THE INVENTION

The present invention relates to a layout structure of a conduction region of a CPU socket, and particularly to a layout structure of a conduction region of a CPU socket with a plurality of vias and contact pads.

### 2. DESCRIPTION OF RELATED ART

A central processing unit (CPU) socket lies on a signal layer of a computer motherboard. The CPU socket has a conduction region for a plurality of filtering capacitors to help provide stable power supply to the CPU.

FIG. 2 shows a conventional layout structure of a conduction region 100 of a CPU socket. The layout structure includes a power plane 60, a ground plane 70, and an insulating barrier 80 for insulating the power plane 60 from the ground plane 70. A plurality of grounding pads 72 is arrayed on the ground plane 70 and a plurality of power pads 62 is arrayed on the power plane 60. Each capacitor (not shown) has two pins respectively connected to a grounding pad and a power pad. It is of disadvantage that the ground plane 70 occupies such a large area of the CPU socket, and thus increases an impedance of the power plane 60, leading to reduced stability in performance of an associated computer system.

What is needed, therefore, is a layout structure of a conduction region of a CPU socket which is able to reduce the impedance of the power plane, and achieve stable performance.

### SUMMARY OF THE INVENTION

A layout structure of a conduction region of a CPU socket is provided. In a preferred embodiment, the layout structure includes: a power plane; and a plurality of pad pairs and grounding vias arrayed on the power plane, each of the pad pairs having a grounding pad and a power supply pad for connecting an electronic component thereon, and each grounding pad being coupled to at least a grounding via, wherein along a same direction of a connection line between the grounding pads and the power supply pads of each of the pad pairs, the power supply pads alternate with the grounding pads. It is of advantage that the layout structure increases an area of the power plane thus reducing the impedance of the power plane.

Other advantages and novel features will become more apparent from the following detailed description when taken in conjunction with the accompanying drawings, in which:

### BRIEF DESCRIPTION OF THE DRAWINGS

FIG. 1 is a schematic diagram of a layout structure of a conduction region 200 of a CPU socket, in accordance with a preferred embodiment of the present invention; and

FIG. 2 is a schematic diagram of a conventional layout structure of a conduction region 100 of a CPU socket.

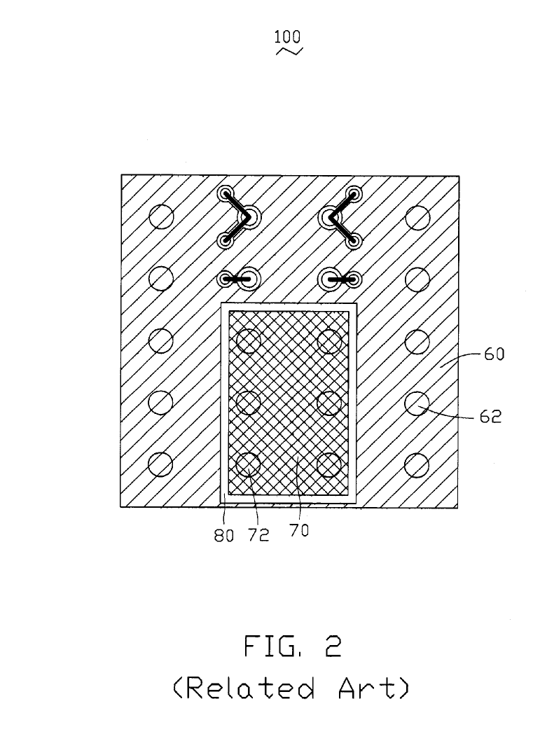

### DETAILED DESCRIPTION OF THE INVENTION

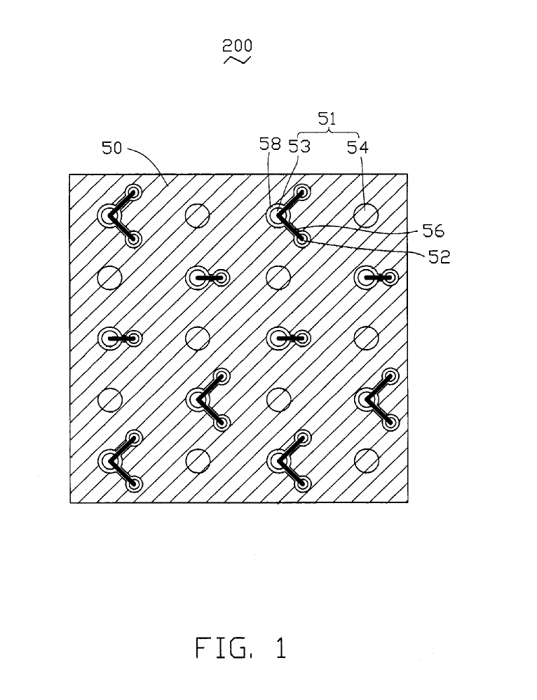

FIG. 1 shows a layout structure of a conduction region 200 of a CPU socket, in accordance with a preferred embodiment of the present invention. The layout structure includes a power plane 50, a plurality of pad pairs 51, and a plurality of grounding vias 52. The pad pairs 51 and the grounding vias 52 are arrayed on the power plane 50. Each of the pad pairs 51 includes a grounding pad 53 and a power supply pad 54 for connecting an electronic component such as a capacitor (not shown) thereon. Each of the grounding pads 53 is coupled to at least a grounding via 52 by at least a conducting wire 56. Isolated areas 58 isolate the conducting wires 56, the grounding pads 53, and the grounding vias 52 from the power plane 50. Along a same direction of a connection line between the grounding pad 53 and the power supply pad 54 of each of the pad pairs 51, the power supply pads 54 alternate with the grounding pads 53. The power supply pads 54 alternating with the grounding pads 53 avoids clustering of the grounding vias 52, which can impair performance of the power plane. Therefore, along a direction vertical line to the connection line between the grounding pad 53 and the power supply pad 54 of each of the pad pairs 51, the power supply pads 54 and the grounding pads 53 are also arrayed in an alternating manner.

Compared with the conventional layout structure, the layout structure of the present invention increases an area of the power plane 60 and reduces the impedance of the power plane 60.

It is believed that the present invention and its advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A layout structure of a conduction region of a central processing unit (CPU) socket, the layout structure comprising:
a power plane; and
a plurality of pad pairs and grounding vias arrayed on the power plane, each of the pad pairs having a grounding pad and a power supply pad for connecting an electronic component thereon, and each grounding pad being coupled to at least a grounding via, wherein along a same direction of a connection line between the grounding pad and the power supply pad of each of the pad pairs, the power supply pads alternate with the grounding pads.

2. The layout structure as claimed in claim 1, wherein each grounding pad is connected to the at least a grounding via by at least a conducting wire.

3. The layout structure as claimed in claim 2, further comprising isolated areas for isolating the conducting wires, the grounding pads, and the grounding vias from the power plane.

4. A layout structure of a conduction region of a central processing unit (CPU) socket, the layout structure comprises:
a power plane; and
a plurality of grounding pads, power supply pads, and grounding vias arrayed on the power plane, each of the grounding pads being coupled to at least a grounding via, the power supply pads and the grounding pads being arrayed in rows and columns in an alternating pattern.

5. The layout structure as claimed in claim 4, wherein each grounding pad is connected to the at least a grounding via by at least a conducting wire.

6. The layout structure as claimed in claim 5, further comprising isolated areas for isolating the conducting wires, the grounding pads, and the grounding vias from the power plane.
